(19) United States
(12) Patent Application Publication
(10) Pub. No.: US 2025/0051921 A1
(43) Pub. Date: Feb. 13, 2025

(54) MULTIPLE-ZONE GAS BOX BLOCK SURFACE HEATER

(71) Applicant: Lam Research Corporation, Fremont, CA (US)

(72) Inventors: Alon Ganany, Portland, OR (US); Pawan M. Patil, Mumbai (IN); John F. Stumpf, Wilsonville, OR (US)

(73) Assignee: Lam Research Corporation, Fremont, CA (US)

(21) Appl. No.: 18/719,769

(22) PCT Filed: Dec. 1, 2022
(86) PCT No.: PCT/US2022/080774

§ 371 Date: Jun. 13, 2024

Related U.S. Application Data
(60) Provisional application No. 63/267,095, filed on Jan. 24, 2022.

(51) Int. Cl. C23C 16/458; C23C 16/46; C23C 16/52; H05B 3/78

(52) U.S. Cl. CPC C23C 16/4586; C23C 16/46; C23C 16/52; H05B 3/78

(57) ABSTRACT

A gas conditioning apparatus comprising a substrate block comprising one or more fluid ports on an upper surface of the substrate block. The substrate block has a first length along a sidewall. The substrate block comprises an inlet port at a first end and an outlet port at a second end. A flow passage extends within the substrate block between the inlet port and the outlet port and is in fluidic communication with the one or more fluid ports. At least one heater strip is on the sidewall of the substrate block. The at least one heater strip extends between the first end and the second end and is to control an internal temperature within a zone of the substrate block. The zone has a second length that is less than or substantially equal to the first length.

### CLAIM OF PRIORITY

This application is a continuation of, and claims the benefit of priority to U.S. Patent Application No. 63/267,095, filed Jan. 24, 2022, titled “MULTIPLE-ZONE GAS BOX BLOCK SURFACE HEATER,” and which is incorporated by reference in its entirety.

### BACKGROUND

Substrate processing tools are used to perform treatments such as deposition and etching of film on substrates like semiconductor wafers. For example, deposition may be performed to deposit a conductive film, a dielectric film, or other types of film using chemical vapor deposition (CVD), plasma enhanced CVD (PECVD), atomic layer deposition (ALD), plasma enhanced ALD (PEALD), and/or other deposition processes. The deposition may be performed in a wafer processing chamber such as a PECVD chamber comprising multiple stations for processing more than one wafer at a time. In some tools, a wafer transfer system may be included within the wafer processing chamber.

Process gases that are fed to a CVD apparatus are generally conditioned before entering the CVD apparatus. Process gases may comprise vapors of substances that may be deposition precursors generally diluted in a carrier gas. A common practice is to pass process gases through a gas box, comprising a modular gas handling system. Such a system may comprise one or more flow blocks mounted on a breadboard. The system may be enclosed in a gas-tight box (gas box) to contain leaks of noxious gases among other reasons. The flow blocks are unitary machined stainless-steel blocks having an internal flow passage for passing gases through. The flow blocks are generally long along the flow passage direction and relatively narrow, thus may be referred to as “sticks”. The internal flow passage may communicate with one or more gas-handling components that are surface mounted on a top surface of the block, also referred to as a substrate. The combination of block substrate and surface mount components may be referred to as a “gas stick”. Process gases flowing through the internal flow passage may flow through some surface mount components. Examples of such components may comprise metering valves, thermocouples, flow-through filters, pressure regulators, mass flow controllers flow and pressure gauges. During passage of a process gas through the flow block, the process gas may encounter a large volume surface mount component, such as a surface mount filter. The gas may expand adiabatically within the volume of the surface mount component. During expansion, the gas temperature may fall below the vaporization temperature of one or more vapors within the process gas, causing condensation of the vapors within the component and/or the internal flow passage.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Also, various physical features may be represented in their simplified “ideal” forms and geometries for clarity of discussion, but it is nevertheless to be understood that practical implementations may only approximate the illustrated ideals. For example, smooth surfaces and square intersections may be drawn in disregard of finite roughness, corner-rounding, and imperfect angular intersections characteristic of structures formed by nanofabrication techniques. Further, where considered appropriate, reference labels have been repeated among the figures to indicate corresponding or analogous elements.

FIG. 1 illustrates a 3-D view of a prior art modular gas flow system comprising an isolated gas stick.

FIG. 2 illustrates a plan view of a prior art multi-stick modular gas flow control system.

FIG. 3 illustrates a 3D view of a gas stick comprising a heater strip along the entire length of a sidewall, according to some embodiments of the disclosure.

FIG. 4 illustrates a 3D view of a gas stick comprising a partial length of a sidewall, according to some embodiments of the disclosure.

FIG. 5 illustrates a 3D view of a gas stick comprising a heater strip on opposing sidewalls, according to some embodiments of the disclosure.

FIG. 6 illustrates a plan view of a heater strip comprising a network of substantially identical resistive elements connected in parallel and distributed along the length of the heater strip, according to some embodiments of the disclosure.

FIG. 7 illustrates a plan view of a heater strip comprising a network of resistive elements having progressively smaller resistance, according to some embodiments of the disclosure.

FIG. 8 illustrates a plan view of a heater strip comprising a network of resistive elements having progressively larger resistance, according to some embodiments of the disclosure.

FIG. 9 illustrates a plan view of a heater strip comprising a network of independently powered resistive elements, according to some embodiments of the disclosure.

FIG. 10 illustrates a plan view of a gas conditioning system enclosed in a gas box, according to some embodiments of the disclosure.

FIG. 11 illustrates a flow chart summarizing an exemplary method for handling a process gas through a gas box, according to some embodiments of the disclosure.

### DETAILED DESCRIPTION

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Also, various physical features may be represented in their simplified “ideal” forms and geometries for clarity of discussion, but it is nevertheless to be understood that practical implementations may only approximate the illustrated ideals. For example, smooth surfaces and square intersections may be drawn in disregard of finite roughness, corner-rounding, and imperfect angular intersections characteristic of structures formed by nanofabrication techniques. Further, where considered appropriate, reference labels have been repeated among the figures to indicate corresponding or analogous elements.

In the following description, numerous specific details are set forth, such as structural schemes, to provide a thorough understanding of embodiments of the present disclosure. It will be apparent to one skilled in the art that embodiments of the present disclosure may be practiced without these specific details. In other instances, well-known features, such as gas line tubing fittings, heating elements and snap switches, are described in lesser detail to not unnecessarily obscure embodiments of the present disclosure. Furthermore, it is to be understood that the various embodiments shown in the figures are illustrative representations and are not necessarily drawn to scale.

In some instances, in the following description, well-known methods and devices are shown in block diagram form, rather than in detail, to avoid obscuring the present disclosure. Reference throughout this specification to “an embodiment” or “one embodiment” or “some embodiments” means that a particular feature, structure, function, or characteristic described in connection with the embodiment is included in at least one embodiment of the disclosure. Thus, the appearances of the phrase “in an embodiment” or “in one embodiment” or “some embodiments” in various places throughout this specification are not necessarily referring to the same embodiment of the disclosure. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical, electrical or in magnetic contact with each other, and/or that the two or more elements co-operate or interact with each other (e.g., as in a cause an effect relationship).

The terms “over,” “under,” “between,” and “on” as used herein refer to a relative position of one component or material with respect to other components or materials where such physical relationships are noteworthy. Unless these terms are modified with “direct” or “directly,” one or more intervening components or materials may be present. Similar distinctions are to be made in the context of component assemblies. As used throughout this description, and in the claims, a list of items joined by the term “at least one of” or “one or more of” can mean any combination of the listed terms.

The term “adjacent” here generally refers to a position of a thing being next to (e.g., immediately next to or close to with one or more things between them) or adjoining another thing (e.g., abutting it).

Unless otherwise specified in the explicit context of their use, the terms “substantially equal,” “about equal” and “approximately equal” mean that there is no more than incidental variation between two things so described. In the art, such variation is typically no more than +/−10% of the referred value.

To address the limitations described herein, a gas stick comprising one or more resistive heater strips attached to the substrate block is described. In some embodiments, the heater strip may comprise multiple resistive elements distributed along the length of the heater strip. In some embodiments, the multiple resistive elements may differentially inject heat into adjacent portions of the substrate block, enabling creation of temperature zones within the gas stick. In some embodiments, process gases may be progressively heated, or large amounts of heat may be injected into a zone of the substrate block to increase heat transfer to flowing gases before the gases pass through a large volume surface mount component such as a filter.

In some embodiments, adjacent resistive elements have different resistances. For example, in some embodiments, adjacent resistive elements may have progressively increasing resistance to create a rapidly increasing temperature profile within a substrate block. In some embodiments, adjacent resistive elements may have progressively decreasing resistance to create a decreasing temperature profile. In other embodiments, adjacent resistive elements having arbitrary resistances may be distributed according to process requirements. In the foregoing, the resistive elements may be powered by a single power source. In alternate embodiments, resistive elements may be individually powered to create an arbitrary temperature profile.

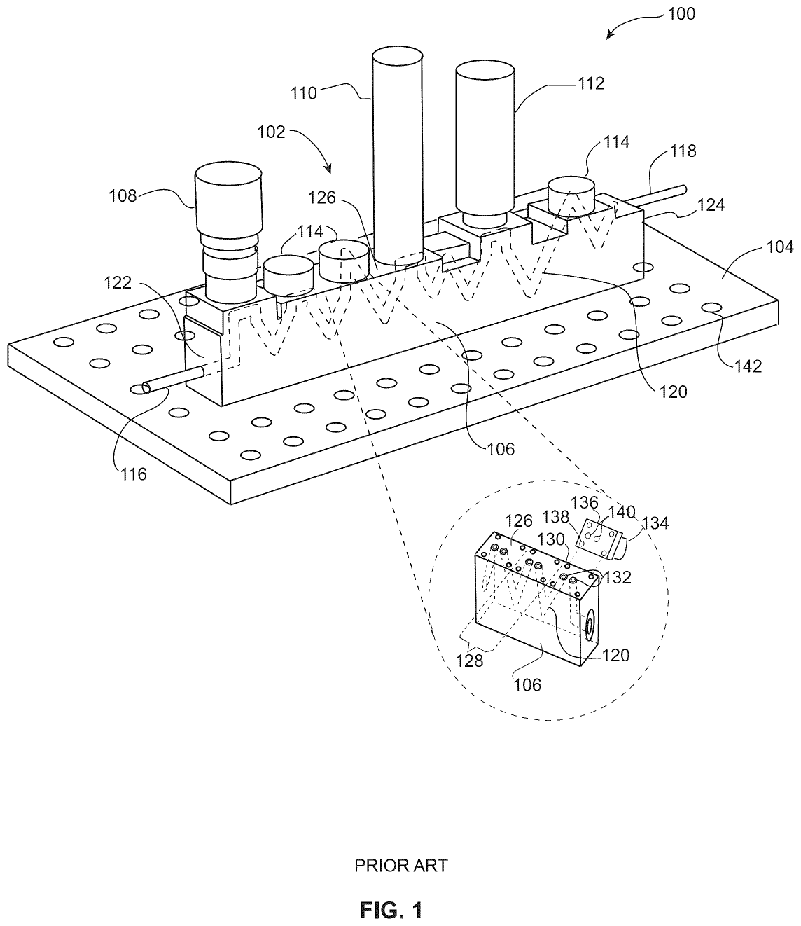

FIG. 1 illustrates a 3-D view of a prior art modular gas flow system 100 comprising isolated gas stick 102, mounted on breadboard 104. In implementations, modular gas flow system 100 may comprise multiple gas sticks, like isolated gas stick 102. Modular gas flow system 100 may be part of an integrated gas conditioning apparatus comprising a gas box system. The gas box system may comprise one or more modular gas flow control units, is described below. Gas stick 102 comprises substrate block 106. In some embodiments, substrate block 106 comprises high temperature and chemically resistant metals such as stainless steel and Hastelloy. Substrate block 106 may be populated by one or more surface mount modular gas flow control components. For example, in the illustrated embodiment gas stick 102 comprises surface mount (e.g., modular) needle valve 108 and surface mount filters 110 and 112. Flow through caps 114 may be interspersed between surface mount flow components.

Inlet tube 116 and outlet tube 118, extending from substrate block 106, may communicate with internal flow passage 120 (shown by the dashed lines). In the illustrated embodiment, internal flow passage 120 may extend from end sidewall 122 to opposing end sidewall 124 along a zig-zag or serpentine path. Segments of internal flow passage 120 may intersect mounting surface 126 of substrate block 106. Openings at surface intersections of internal flow passage 120 may enable communication of internal flow passage 120 with surface mount flow components.

Referring to the inset, modular surface mount components may be fastened to mounting surface 126 of substrate block 106, in accordance with some embodiments. For example, mounting surface 126 may comprise multiple adjacent component bays 128 for seating surface mount components as shown delineated by dashed lines between adjacent bolt holes 130. In some embodiments, component bays 128 may comprise one or more fluid ports 132. Fluid ports 132 may coincide with intersections of internal flow passage 120 with mounting surface 126. In some embodiments, fluid ports 132 may be recessed (e.g., by counterbore) below mounting surface 126 to seat a seal such as an o-ring, gasket or other type of seal (e.g., C seal or W seal).

In some embodiments, fluid ports 132 may fluidically communicate with segments of internal flow passage 120 extending below fluid ports 132 into the interior of substrate block 106. As noted herein, segments of internal flow passage 120 are shown as hidden lines to indicate passage within the interior of substrate block 106. Segments of internal flow passage 120 may extend at oblique angles into the interior of substrate block 106. Intersecting segments of internal fluid passage 120 may form V-shaped junctions, as shown.

In some embodiments, component bays 128 may comprise threaded bolt holes 130 (e.g., 10-32 threads) arranged in a square pattern within each component bay 128. In some embodiments, bolt holes 130 may occupy corners of each component bay 128.

Referring again to the inset, a surface mount flow component 134 is shown viewing from mounting base 136. In some embodiments, mounting base 136 may generally have a square perimeter of standard dimensions, for example, to fit component bays 128. In some embodiments, mounting base 136 may comprise through-holes 138 arranged in a square pattern. In some embodiments, through-holes 138 may align with bolt holes 130 within component bays 128 for bolting of surface mount flow component 134 to substrate block 106.

Continuing to refer to the inset, mounting base comprises two fluid ports 140, providing an inlet and outlet for flow of a gas or liquid through surface mount flow component 134, in accordance with some embodiments. In some embodiments, surface mount flow component 134 may be a pressure gauge that comprises a single fluid port 140 for static measurement of fluid pressure. In some embodiments, fluid ports 140 on surface mount component 134 may align to fluid ports 132 on mounting surface 126. As noted herein, fluid ports 132 may be counterbored for placement of a gasket (not shown). Fastening of mounting base 136 to mounting surface 126 may compress a gasket, such as an elastomeric o-ring or metallic C-seal, for example, to form a gas-tight seal that may withstand high pressures.

Gases or liquids flowing within internal flow passage 120 may flow into fluid ports 140 on surface-mount flow component 134. Modular surface mount components mentioned herein (e.g., needle valve 108, surface mount filters 110 and 112) may have a dedicated function, for example filtration of particulates from a gas. Other surface mount components may be pressure regulators and mass flow controllers, in accordance with some embodiments. Temperature control may be limited or absent due to lack of efficient heating means. Unregulated temperature control may cause problems transporting some vaporized materials within internal flow passage 120. For example, condensation of some vapors may occur in cold regions of gas stick 102.

In more extensive modular flow control systems, multiple gas sticks may be attached to breadboard 104 adjacent to gas stick 102. Breadboard 104 may comprise multiple threaded bolt holes 142 (e.g., 10-32 threads) in a regularly spaced array for fastening substrate blocks (e.g., substrate blocks 106) to breadboard 104.

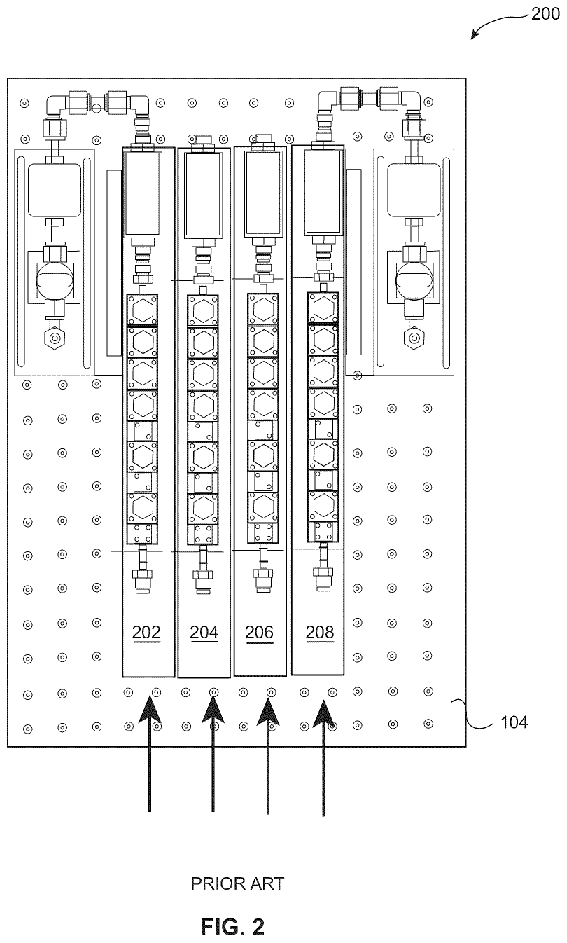

FIG. 2 illustrates a plan view of a prior art multi-stick modular gas flow control system 200. In some implementations, modular gas flow control system 200 may comprise multiple process steams, indicated by the arrows. Each process stream may flow through a gas stick. For example, modular gas flow control system 200 may comprise multiple gas sticks 202, 204, 206, and 208 mounted on breadboard 104.

In some embodiments, modular gas flow control system 200 may be housed within a gas box. In some embodiments, the gas box may be gas tight enclosure to prevent leaks of toxic gases and vapors. Space constraints may force multiple process streams to occupy a small footprint. In some embodiments, breadboard 104 may be densely populated. In some embodiments, process streams may be configured in parallel, for example, within a compact region of breadboard 104. For example, adjacent gas sticks 202-208 may be confined, as shown, to a small portion on breadboard 104. Space in between gas sticks may be constrained as shown in the illustrated embodiment.

In some implementations, temperature control of process gases or liquid flowing through gas sticks 202-208 may be needed to prevent condensation of vapors or precipitation of solids within the internal flow passage (e.g., internal flow passage 120). In a crowded configuration as shown in FIG. 2, inclusion of conventional temperature control componentry may be difficult to implement for densely populated breadboards as shown in FIG. 2, where gas sticks 202-208 are mounted side-by-side with restricted space in between.

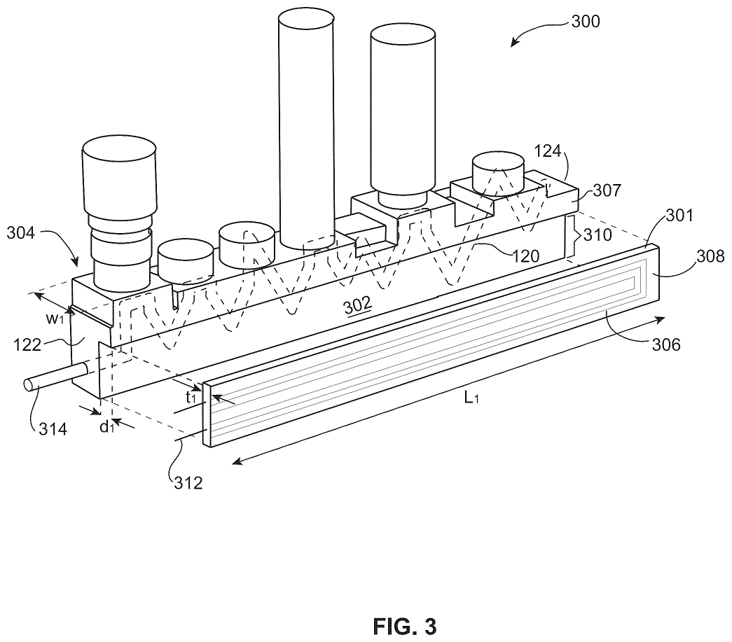

FIG. 3 illustrates a 3D view of gas stick 300, in accordance with some embodiments. As a solution to provision of heat input to process streams flowing within closely spaced gas sticks employed in a modular gas flow control system (e.g., modular gas flow control system 200), gas stick 300 may comprise heater strip 301 attached to sidewall 302 of substrate block 304. Heater strip 301 may comprise resistive heating elements in the form of thin resistive wires 306 embedded in a polymer support 308. In some embodiments, resistive wires 306 may comprise nickel-chromium alloys (e.g., Nichrome). Polymer support 308 may comprise a polyimide (e.g., Kapton), for example, in the form of an adhesive tape. In some embodiments, sidewall 302 along the entire length L1 of substrate block 304 for flush mounting of heater strip 301.

In some embodiments, heater strip 301 may provide heat to gases or liquids flowing within internal flow passage 120 by resistive heating. In the illustrated embodiment, internal flow passage 120 extends from end sidewall 122 to opposing end sidewall 124. Gases, for example, may be introduced at inlet 314. In the illustrated embodiment, heater strip 301 may extend along sidewall 302 to provide heat along the entire length L1 of internal flow passage 120. To increase heat transfer from heater strip 301 to internal flow passage 120, lower portion 310 of sidewall 302 may be recessed by depth d1, according to some embodiments. Recess depth d1 may be adjusted to optimize heat transfer from heater strip 301 to internal flow passage 120. In some embodiments, internal flow passage 120 may pass through a center plane of substrate block 304. Upper portion 307 may overhang lower portion 310, leaving enough lateral space for surface-mount components. By recessing lower portion 310, the thickness of block material between heater strip 301 and internal flow passage 120 may be reduced by recess depth d1. In some embodiments, the recess depth d1 may be approximately equal to or greater than thickness t1 of heater strip 301. Advantageously, recessed lower portion 310 of sidewall 302 may also enable attachment of heater strip 301 on gas stick 300 without increasing overall width w1 of substrate block 304.

For high-density modular flow control systems, multiple heated gas sticks 300 may be laid side-by-side in close proximity to economize space. For example, closely spaced gas sticks (e.g., as shown in FIG. 2) may comprise recessed sidewalls (e.g., lower portion 310 of sidewall 302) as described for gas stick 300. Heater strips (e.g., heater strip 301) may be employed as described herein to provide controlled heat to process streams. In some embodiments, heater strips 301 may be electrically coupled to a temperature controller unit though leads 312, for example, for active temperature control. In some embodiments, thermocouples (not shown), also coupled to the temperature controller unit, may be attached to substrate block 304 at strategic placements. The temperature controller unit may provide electric current through leads 312 to resistive wires 306 for proportional-integral-differential (PID) or other type of control of block temperature along length L1. In some embodiments, substrate block 304 may comprise multiple temperature zones that may be actively controlled.

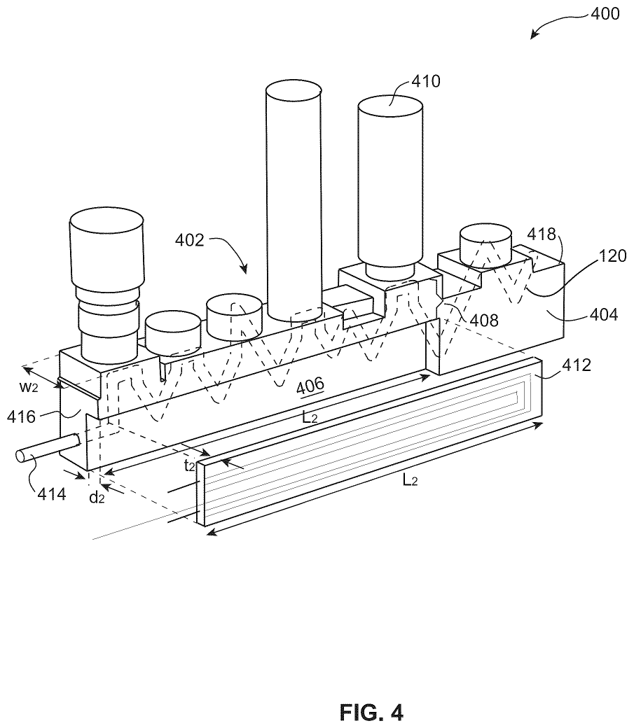

FIG. 4 illustrates a 3D view of gas stick 400, in accordance with some embodiments. In some embodiments, gas stick 400 comprises substrate block 402. In the illustrated embodiment, substrate block 402 is a partially recessed sidewall 404. In the illustrated embodiment, sidewall 404 comprises lower portion 406 that is recessed along a length L2 of substrate block 402. In some embodiments, length L2 may be a portion of total length L1 of substrate block 402. Lower portion 406 may be recessed by a depth d2. In some embodiments, d2 may be adjusted to optimize heat transfer to internal flow passage 120. In some embodiments, internal flow passage 120 may pass through a center plane cutting through substrate block 402. Upper portion 408 of sidewall 404 may overhang lower portion 406, leaving adequate lateral space (e.g., width w2) to accommodate mounting requirements for surface mount components (e.g., surface mount filter 410).

Gas stick 400 comprises heater strip 412, substantially similar to heater strip 301 described herein. Heater strip 412 may have length L2 to fit within recessed lower portion 406 of sidewall 404. A partial coverage of substrate block 402 by heater strip 412 may be desirable if some surface mount componentry located at the ends of substrate block 402 does not require heat input. In other embodiments, substrate block 402 may extend beyond surface mount componentry. For example, gases introduced into gas stick 400 through input tube 414 may flow through internal flow path 120 from endwall 416 to endwall 418. Heating characteristics may only require that internal flow passage 120 be heated along a portion of the total length (e.g., L2).

In some embodiments, heater strip 412 may comprise multiple resistances for differential heat output along length L2. As will be described below, gas stick 500 may be differentially heated in two or more zones along its length L1.

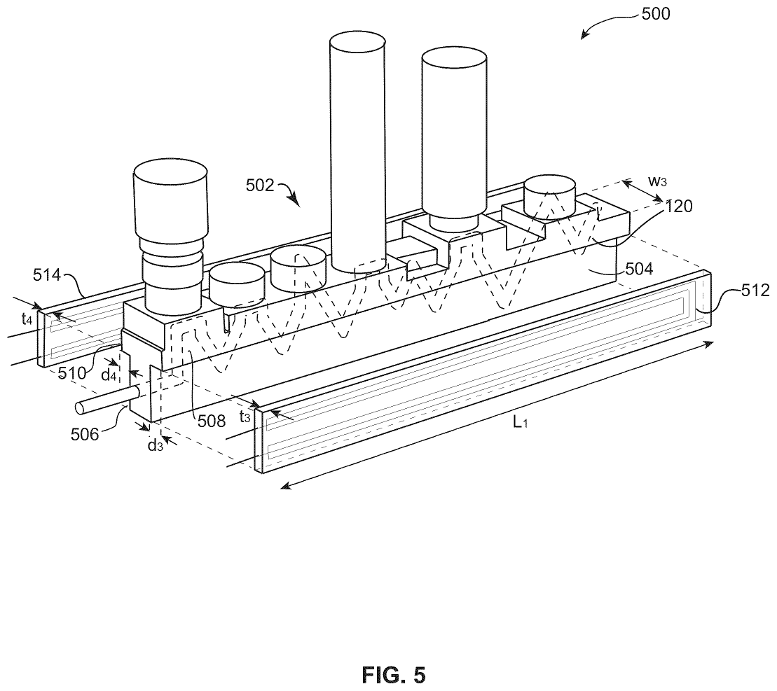

FIG. 5 illustrates a 3D view of gas stick 500, in accordance with some embodiments. In the illustrated embodiment, gas stick 500 comprises substrate block 502, comprising opposing recessed sidewalls 504 and 506. In some embodiments, substrate block 502 comprises overhanging sidewalls 508 and 510 over recessed sidewalls 504 and 506, respectively, extending along length L1 of substrate block 502. In some embodiments, recessed sidewalls 504 and 506 may partially extend along length L1, as shown in FIG. 4. Overhanging sidewalls 508 and 510 may be separated by width w3 for maintenance of width requirements of surface mount componentry. Sidewalls 504 and 506 may be recessed by depths d3 and d4, respectively, to accommodate heater strips 512 and 514. In some embodiments, d3 and d4 are substantially equal. In some embodiments, d3 and d4 may be equal to or greater than thicknesses t3 and t4 of heater strips 512 and 514.

In some embodiments, heater strips 512 and 514 may be substantially similar to heater strips 301 or 412, described herein. Relative to single sidewall gas stick embodiments 300 and 400, heater strips 512 and 514 on opposing sidewalls of gas stick 500 may double heat transfer to gases (or liquids) flowing in internal flow passage 120, in accordance with some embodiments. In some embodiments, heater strips 512 and 514 may inject equal or different amounts of heat into substrate block 502. In some embodiments, recess depths d3 and d4 may be adjusted to optimize heat transfer to a center plane of substrate block 502 comprising internal flow passage 120. Gas stick 500 may provide an advantage of significantly increasing flow rate, for example, while heating gases passing through gas stick 500 to desired temperatures. In some embodiments, heater strips 512 and 514 may comprise multiple resistances for differential heat output along length L1. As will be described herein, gas stick 500 may be differentially heated in two or more zones along length L1.

The following paragraphs describe various embodiments of heater strips.

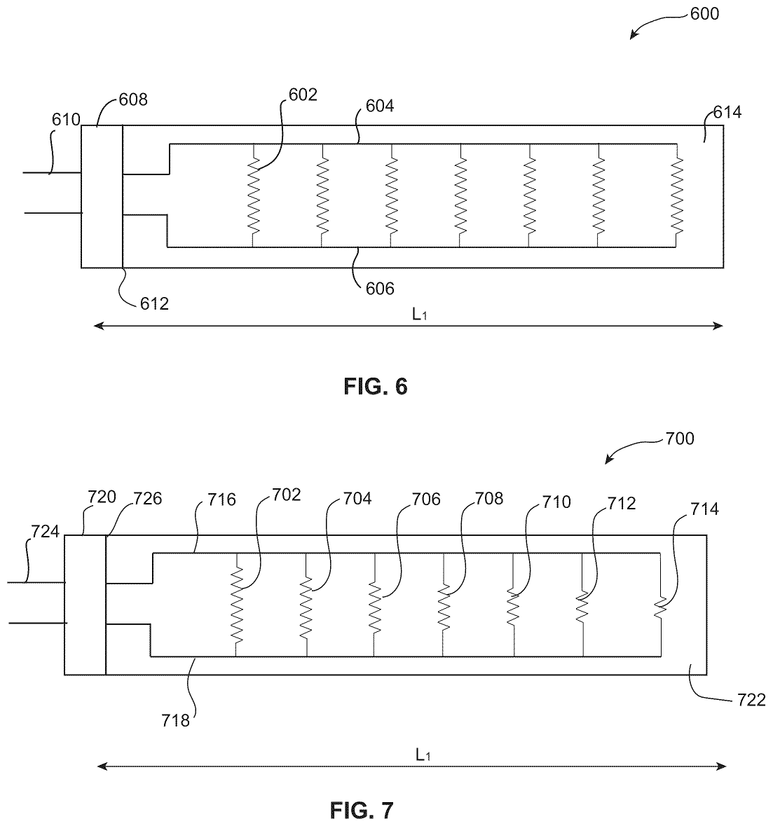

FIG. 6 illustrates a plan view of heater strip 600, in accordance with some embodiments. As noted herein, heater strip 600 may comprise multiple resistive elements 602 distributed in parallel along length L3. In the illustrated embodiment, resistive elements 602 may be represented schematically by the schematic symbol for a resistor. In some embodiments, resistive elements 602 may be a coil of resistive wire. In some embodiments, resistive elements 602 may be a straight wire having a high resistance. In some embodiments, resistive elements 602 may be serpentine or zig-zag wire structures. In some embodiments, resistive elements 602 may be substantially identical, for example having substantially the same electrical resistance R.

In some embodiments, resistive elements 602 may be electrically coupled to distribution wires 604 and 606. In some embodiments, heater strip may comprise connector 608. In some embodiments, leads 610 may extend from connector 608 as prongs. In some embodiments, leads 610 may extend directly from end 612 as shown previously.

In some embodiments, resistive elements 602 comprise high resistance wires comprising materials such as, but not limited to, nickel-chromium alloys (e.g., nichrome), tungsten or titanium. In some embodiments, resistive elements 602 may comprise carbon fiber or film. In some embodiments, resistive elements 602 and distributed wires 604 and 606, may be embedded within carrier 614. In some embodiments, carrier 614 comprises a dielectric matrix comprising a high-temperatures polymer, such as, but not limited to, polyimides (e.g., Kapton) and polyfluorocarbons (e.g., Teflon).

In some embodiments, leads 610 may be electrically coupled to a temperature controller that supplies current to resistive elements 602. Electric current I may be distributed to each resistive element 602 by distribution wires 604 and 606. In some embodiments, I current may be distributed to resistive elements 602 substantially equally. During operation, I²R Joule heat generation along length L1 may be substantially uniform as a result. In various embodiments, heater strip 600 may inject heat substantially uniformly into a gas stick substrate block (e.g., gas stick 300) along length L1

FIG. 7 illustrates a plan view of heater strip 700, in accordance with some embodiments. In some embodiments, heater strip 700 comprises resistive elements 702, 704, 706, 708, 710, 712, and 714 along length L1. In some embodiments, resistive elements 702-714 have progressively smaller resistances along L1, as indicated by the progressively smaller resistor symbols. Resistive elements 702-714 may be connected in parallel to distribution wires 716 and 718. In some embodiments, heater strip 700 may comprise connector 720 extending from carrier 722. In some embodiments, carrier 722 may be substantially similar to carrier 614, described above. In some embodiments, leads 724 may extend from connector 720 or directly from end 726 of carrier 722. Leads 724 may be electrically coupled to distribution wires 716 and 718.

During operation, leads 724 may be electrically coupled to a temperature controller, in accordance with some embodiments. Current may flow along distribution wires 716 and 718, distributed along length L1 to each of resistive elements 702-714. During operation, I²R Joule power generation may progressively increase at each resistive element 702-714 along length L1, progressively increasing heat transfer into the substrate block. For example, heater strip 700 may be employed to inject differential heat into a gas stick comprising multiple static temperature zones along its length. The multiple static temperature zones may have progressively hotter temperatures along the length of the gas stick. Such a configuration may be advantageous for expansion of gases within a large volume surface mount component, such as a filter component (e.g., surface mount filters 110 and 112) or a mass flow controller. For example, gases may expand adiabatically within large-volume surface mount components, losing heat. Condensation of vapors may occur within the surface mount component or within the internal flow path (e.g., internal flow passage 120), for example. Increasing heat transfer in a zone of the gas stick that coincides with a surface mount component, such as surface mount filter 110 and 112, may mitigate such condensation.

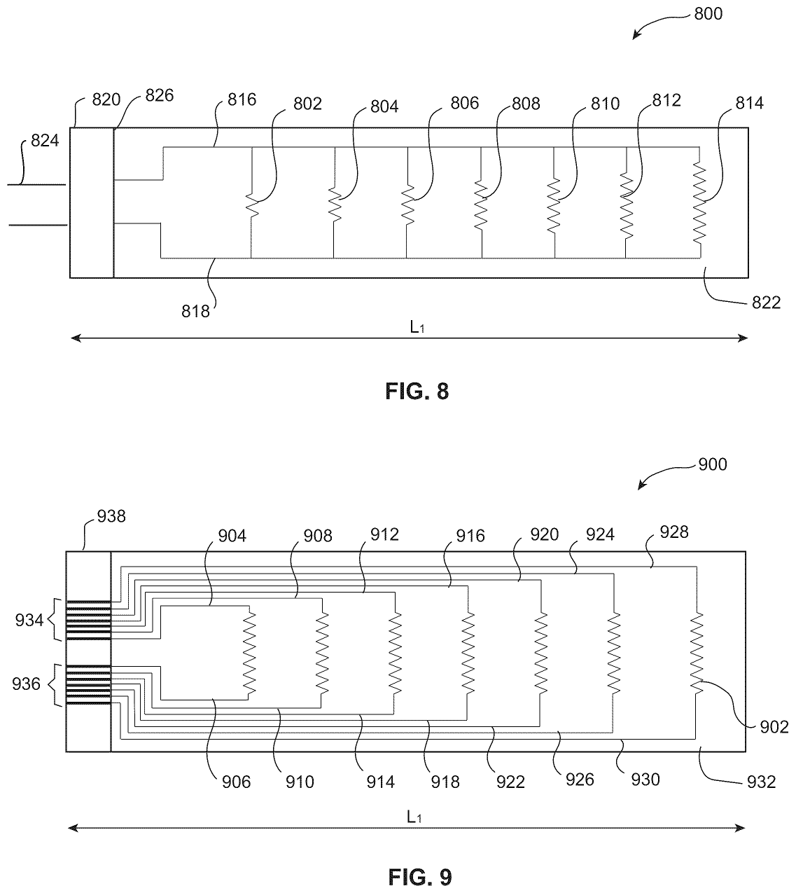

FIG. 8 illustrates a plan view of heater strip 800, in accordance with some embodiments. In some embodiments, heater strip 800 comprises resistive elements 802, 804, 806, 808, 810, 812 and 814 distributed along length L1. Resistive elements 802-814 may be connected in parallel to distribution wires 816 and 818. In some embodiments, resistive elements 802-814 have progressively larger resistances along L1, as indicated by the progressively larger resistor symbols (e.g., reverse order relative to heat strip 700). Resistive elements 802-814 may be connected in parallel to distribution wires 816 and 818. In some embodiments, heater strip 800 may comprise connector 820 extending from carrier 822. In some embodiments, carrier 822 may be substantially similar to carrier 722, described above. In some embodiments, leads 824 may extend from connector 820 or directly from end 826 of carrier 822. Leads 824 may be electrically coupled to distribution wires 816 and 818.

During operation, leads 824 may be electrically coupled to a temperature controller, in accordance with some embodiments. Current may flow along distribution wires 816 and 818, distributed along length L1 to each of resistive elements 802-814. During operation, I²R Joule power generation may progressively decrease at each resistive element 802-814 along length L1, progressively increasing heat transfer into the substrate block by I²R Joule heating.

In some embodiments, heater strip 800 may be employed to differentially inject heat into a gas stick comprising multiple static temperature zones along its length. The multiple static temperature zones may have progressively cooler temperatures along the length of the gas stick. Such a configuration may be advantageous for gas stick assemblies comprising large volume surface mount components, such as a filter component (e.g., surface mount filters 110 and 112) or a mass flow controller, mounted near the entrance of a gas stick, for example. The gas stick may comprise zones of highest temperature close to the entrance of gases into the gas stick. Large heat injection within the entrance zones may enable gases to expand quasi-isothermally, mitigating potential condensation as noted above.

FIG. 9 illustrates a plan view of heater strip 900, in accordance with some embodiments. In some embodiments, heater strip 900 comprises resistive elements 902, distributed along length L1. Resistive elements 902 may be substantially identical, having substantially the same resistance R. In the illustrated embodiment, each resistive element 902 is individually connected to pairs of return wires (e.g., return wire pairs 904 and 906, 908 and 910, 912 and 914, 916 and 918, 920 and 922, 924 and 926, and 928 and 930). All wires may be embedded in carrier 932. In the illustrated embodiment, return wire pairs 904-930 may be connected to sets of contacts 934 and 936 (e.g., pin sockets or pins) in connector 938. Connector 938 may be a flat ribbon connector, for example.

During operation, an individual resistive element 902 may be independently connected to a power source through multi-contact connector 934. Power fed into an individual resistive element 902 may be varied independently of the others. Differential heat injection may have an arbitrary pattern for flexibly accommodating temperature control requirements for a particular gas stick. For example, highest heat input may be concentrated at the center portion of a gas stick, where a large volume surface mount component may be attached.

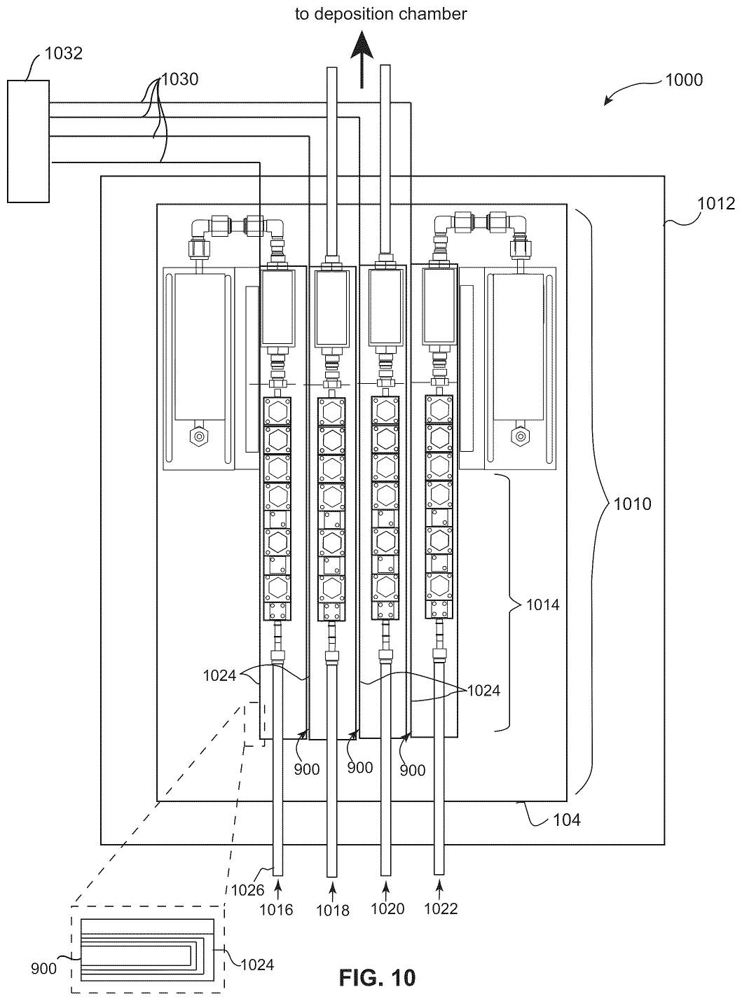

FIG. 10 illustrates a profile view of gas box 1000 comprising modular gas flow controller system 1010 within enclosure 1012, in accordance with some embodiments. In the illustrated embodiment, modular gas flow control system 1010 comprises multiple gas sticks 1014 for handling incoming process gases from process streams 1016, 1018, 1020 and 1022. In the illustrated embodiment, gas sticks 1014 are substantially identical, comprising the same surface mount componentry. In alternate embodiments, individual gas sticks 1014 may comprise different arrays of surface mount componentry to meet requirements for a particular process stream. Gas sticks 1014 are mounted on breadboard 104 in a compact side-by-side configuration, leaving little space between sidewalls 1024. In some embodiments, process gases are piped to gas sticks though tubing 1026. Process gases may comprise vapors of liquids or solids (e.g., by sublimation) that are used as precursor substances for chemical vapor deposition (CVD) processes. The CVD processes may be performed in a deposition chamber downstream of gas box 1000, for example. Precursor vapors may be entrained in an inert carrier gas at relatively low concentrations. Precursor vapors may have low vapor pressures at processes temperatures. Below a critical temperature, the vapors may condense to a liquid or solid state.

In some embodiments, each of gas sticks 1014 may comprise multiple temperature zones. Gas sticks 1014 may comprise heater strip 900 attached to sidewalls 1024. Heater strips 600, 700 or 800 may also be employed to satisfy process requirements. As described herein, heater strip 900 comprises multiple resistive elements (e.g., resistive element 902) distributed along its length L1. An individual resistive element 902 may be independently powered so that arbitrary temperature profiles may be created. As noted herein, resistive elements 902 may be electrically coupled to a flat ribbon connector (e.g., connector 938). In the illustrated embodiment, cables 1030 couple resistive elements in heater strips 900 to temperature controller 1032. In some embodiments, cables 1030 may be flat ribbon cables. In some embodiments, cables 1030 may also carry leads from thermocouples to temperature controller 1032. In some embodiments, temperature controller 1032 may comprise multiple independent power channels. An individual channel may provide power to each independent resistive element in the four heater strips 900. Independently controlled temperature zones within an individual gas stick 1014 may be created by heater strips 900.

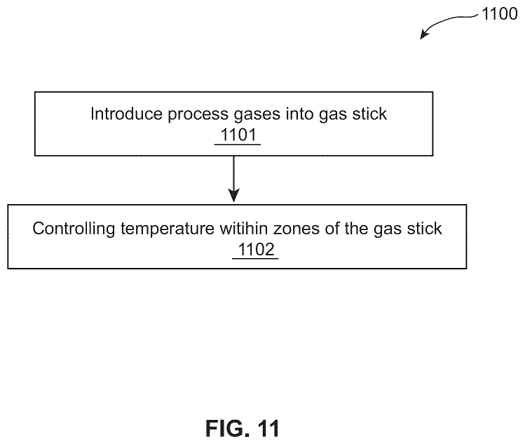

FIG. 11 illustrates flow chart 1100 summarizing an exemplary method for handling a process gas, in accordance with some embodiments. In some embodiments, one or more operations described herein may be performed by hardware, software, or a combination of them. While the order of operations is presented in a particular order, the order can be modified. For example, some operations may be performed in parallel. At operation 1101, a process gas is introduced into a gas box (e.g., gas box 1000) comprising a modular gas flow control system (e.g., modular gas flow control system 1010). The modular gas flow control system may comprise one or more gas sticks as described above (e.g., any of gas sticks 300, 400 or 500 described herein). The process gas may comprise vapors of precursor substances that may be employed in a CVD process. Vapors may be formed at elevated temperatures and may condense if exposed to lower temperatures. The flow path must be maintained above the vaporization (or sublimation) temperatures.

In some embodiments, the gas stick may comprise an adhesive heater strip attached to one sidewall (e.g., gas stick 300 or 400). In some embodiments, two heater strips may be attached to both sidewalls (e.g., gas stick 500). The heater strip may comprise multiple resistive elements distributed along its length, as described herein for heater strips 600, 700, 800 and 900. The gas stick may comprise temperature zones coinciding with positions of surface mount components. For example, surface mount filters may be located near the exit end of the gas stick. Gases flowing along an internal flow path within the substrate block of the gas stick (e.g., internal flow passage 120) may expand adiabatically when flowing into the surface mount filter component. During expansion, the gas temperature may decrease. To mitigate condensation of some vapors, the process gas may be heated to a threshold temperature before entering the filter component, in accordance with some embodiments.

At operation 1102, the resistive elements of the heater strip may be independently powered to create an arbitrary temperatures profile along the length of the gas stick substrate (e.g., heater strip 900), in accordance with some embodiments. For example, if the filter component is located midway between the inlet and outlet of the gas stick, resistive elements in a center portion of the heater strip may receive a larger amount of power than other resistive elements near terminal portions. The larger power input to the center elements may enable injection of adequate heat at the center region of the gas stick to mitigate condensation upon expansion within the filter component.

Following examples are provided that illustrate the various embodiments. The examples can be combined with other examples. As such, various embodiments can be combined with other embodiments without changing the scope of the invention.

Example 1 is a gas conditioning apparatus comprising a substrate block comprising one or more fluid ports on an upper surface of the substrate block, wherein the substrate block has a first length along a sidewall, the substrate block comprising an inlet port at a first end and an outlet port at a second end, and wherein a flow passage extends within the substrate block between the inlet port and the outlet port and fluidically communicates with the one or more fluid ports, and at least one multiple zone heater strip on the sidewall of the substrate block, wherein the at least one heater strip extends between the first end and the second end and controls an internal temperature within a zone of the substrate block, wherein the zone has a second length that is less than or substantially equal to the first length.

Example 2 includes all of the features of example 1, wherein the zone is a first zone, wherein the first temperature zone is to have a first temperature, wherein a second temperature zone is adjacent to the first temperature zone, the second temperature zone is to have a second temperature that is substantially different from or substantially equal to the first temperature.

Example 3 includes all of the features of example 1, wherein the at least one multiple zone heater strip comprises a plurality of resistive elements electrically coupled in parallel, wherein the plurality of resistive elements is distributed along the first length of the sidewall of the substrate block, wherein the substrate block comprises a plurality of temperature zones, and wherein ones of the plurality of resistive elements are each adjacent to ones of the plurality of temperature zones.

Example 4 includes all of the features of example 3, wherein the plurality of resistive elements comprises a first resistive element and an adjacent second resistive element, wherein the first resistive element has a first resistance and a second resistive element has a second resistance, and wherein the first resistance is greater than the second resistance.

Example 5 includes all of the features of example 3, wherein the ones of the plurality of resistive elements are distributed along the first length of the sidewall of the substrate block, and wherein the resistance of the ones of the plurality of resistive elements progressively decreases from the first end to the second end.

Example 6 includes all of the features of example 3, wherein individual ones of the plurality of resistive elements are each electrically coupled to an independent power source.

Example 7 includes all of the features of example 6, wherein the sidewall is a first sidewall, the at least one heater strip comprises a first heater strip, wherein the substrate block comprises a second sidewall opposite the first sidewall, the second sidewall has a third length, and wherein a second heater strip is attached along the second sidewall and extends along the third length.

Example 8 includes all of the features of example 7, wherein the second heater strip is substantially identical to the first heater strip.

Example 9 includes all of the features of example 1, wherein the sidewall comprises a recessed portion, wherein the recessed portion has a third length that is less than or equal to the first length, wherein the heater strip extends along the recessed portion, and wherein the heater strip has a fourth length that is less than or approximately equal to the third length.

Example 10 includes all of the features of example 3, wherein the at least one heater strip comprises the plurality of resistive elements embedded within a polymer film.

Example 11 includes all of the features of example 10, wherein the polymer film comprises a polyimide or a polyfluorocarbon.

Example 12 is a system, comprising a gas conditioning apparatus comprising a substrate block comprising one or more fluid ports on an upper surface of the substrate block, the substrate block has a first length along a sidewall, the substrate block comprising an inlet port at a first end and an outlet port at a second end, and wherein a flow passage extends within the substrate block between the inlet port and the outlet port and fluidically communicates with the one or more fluid ports, and at least one heater strip on the sidewall of the substrate block, wherein the at least one heater strip controls an internal temperature within a temperature zone of the substrate block, and wherein the temperature zone has a second length that is at least a portion of the first length, and wherein the at least one heater strip is electrically coupled to a heater controller.

Example 13 includes all of the features of example 12, wherein the gas conditioning apparatus is within an enclosure.

Example 14 includes all of the features of example 12, wherein the substrate block comprises multiple temperature zones.

Example 15 includes all of the features of example 12, wherein the heater strip comprises multiple resistive elements.

Example 16 includes all of the features of 15, wherein the heater controller comprises multiple power channels electrically coupled to the multiple resistive elements.

Example 17 is a method for handling a process gas, comprising introducing a process gas into a gas conditioning apparatus comprising a substrate block comprising one or more fluid ports on an upper surface of the substrate block, the substrate block has a first length along a sidewall, the substrate block comprising an inlet port at a first end and an outlet port at a second end, and wherein a flow passage extends within the substrate block between the inlet port and the outlet port and fluidically communicates with the one or more fluid ports, and at least one heater strip on a sidewall of the substrate block, and controlling temperatures within zones of the substrate block.

Example 18 includes all of the features of example 17, wherein controlling the temperatures within zones of the substrate block comprises electrically coupling the at least one heater strip to a heater controller.

Example 19 includes all of the features of example 18, wherein the at least one heater strip comprises a plurality of resistive elements electrically coupled to the heater controller, wherein the plurality of resistive elements comprise individual resistive elements distributed along the at least one heater strip.

Example 20 includes all of the features of example 19, wherein adjacent ones of the plurality of resistive elements comprise different resistances.

Example 21 includes all of the features of example 20, wherein adjacent ones of the plurality of resistive elements have progressively smaller resistances wherein temperature decreases along the heater strip from a first resistive element having a highest resistance to a terminal resistive element having a lowest resistance.

Example 22 includes all of the features of example 20, wherein adjacent ones of the plurality of resistive elements have progressively larger resistances, wherein temperature decreases along the heater strip from a first resistive element having a lowest resistance to a terminal resistive element having a highest resistance.

Besides what is described herein, various modifications may be made to the disclosed embodiments and implementations thereof without departing from their scope. Therefore, illustrations of embodiments herein should be construed as examples only, and not restrictive to the scope of the present disclosure. The scope of the invention should be measured solely by reference to the claims that follow.

1. A gas conditioning apparatus comprising:
a substrate block comprising one or more fluid ports on an upper surface of the substrate block, wherein the substrate block has a first length along a sidewall, the substrate block comprising an inlet port at a first end and an outlet port at a second end, and wherein a flow passage extends within the substrate block between the inlet port and the outlet port and fluidically communicates with the one or more fluid ports; and
at least one multiple zone heater strip on the sidewall of the substrate block,
wherein the at least one multiple zone heater strip extends between the first end and the second end and controls an internal temperature within a zone of the substrate block, wherein the zone has a second length that is less than or substantially equal to the first length.

2. The gas conditioning apparatus of claim 1, wherein the zone is a first zone, wherein the first zone is to have a first temperature, wherein a second zone is adjacent to the first zone, the second zone is to have a second temperature that is substantially different from or substantially equal to the first temperature.

3. The gas conditioning apparatus of claim 1, wherein the at least one multiple zone heater strip comprises a plurality of resistive elements electrically coupled in parallel, wherein the plurality of resistive elements is distributed along the first length of the sidewall of the substrate block, wherein the substrate block comprises a plurality of temperature zones, and wherein ones of the plurality of resistive elements are each adjacent to ones of the plurality of temperature zones.

4. The gas conditioning apparatus of claim 3, wherein the plurality of resistive elements comprises a first resistive element and an adjacent second resistive element, wherein the first resistive element has a first resistance and a second resistive element has a second resistance, and wherein the first resistance is greater than the second resistance.

5. The gas conditioning apparatus of claim 3, wherein the ones of the plurality of resistive elements are distributed along the first length of the sidewall of the substrate block, and wherein resistance of the ones of the plurality of resistive elements progressively decreases from the first end to the second end.

6. The gas conditioning apparatus of claim 3, wherein individual ones of the plurality of resistive elements are each electrically coupled to an independent power source.

7. The gas conditioning apparatus of claim 6, wherein the sidewall is a first sidewall, the at least one multiple zone heater strip comprises a first heater strip, wherein the substrate block comprises a second sidewall opposite the first sidewall, the second sidewall has a third length, and wherein a second heater strip is attached along the second sidewall and extends along the third length.

8. The gas conditioning apparatus of claim 7, wherein the second heater strip is substantially identical to the first heater strip.

9. The gas conditioning apparatus of claim 1, wherein the sidewall comprises a recessed portion, wherein the recessed portion has a third length that is less than or equal to the first length, wherein the at least one multiple zone heater strip extends along the recessed portion, and wherein the at least one multiple zone heater strip has a fourth length that is less than or approximately equal to the third length.

10. The gas conditioning apparatus of claim 3, wherein the at least one multiple zone heater strip comprises the plurality of resistive elements embedded within a polymer film.

11. The gas conditioning apparatus of claim 10, wherein the polymer film comprises a polyimide or a polyfluorocarbon.

12. A system, comprising:
a gas conditioning apparatus comprising:
a substrate block comprising one or more fluid ports on an upper surface of the substrate block, the substrate block has a first length along a sidewall, the substrate block comprising an inlet port at a first end and an outlet port at a second end, and wherein a flow passage extends within the substrate block between the inlet port and the outlet port and fluidically communicates with the one or more fluid ports; and
at least one heater strip on the sidewall of the substrate block, wherein the at least one heater strip controls an internal temperature within a temperature zone of the substrate block, and wherein the temperature zone has a second length that is at least a portion of the first length, and wherein the at least one heater strip is electrically coupled to a heater controller.

13. The system of claim 12, wherein the gas conditioning apparatus is within an enclosure.

14. The system of claim 12, wherein the substrate block comprises multiple temperature zones.

15. The system of claim 12, wherein the at least one heater strip comprises multiple resistive elements.

16. The system of claim 15, wherein the heater controller comprises multiple power channels electrically coupled to the multiple resistive elements.

17. A method for handling a process gas, comprising:
introducing the process gas into a gas conditioning apparatus comprising:
a substrate block comprising one or more fluid ports on an upper surface of the substrate block, the substrate block has a first length along a sidewall, the substrate block comprising an inlet port at a first end and an outlet port at a second end, and wherein a flow passage extends within the substrate block between the inlet port and the outlet port and fluidically communicates with the one or more fluid ports; and
at least one heater strip on the sidewall of the substrate block; and
controlling temperatures within zones of the substrate block.

18. The method of claim 17, wherein controlling the temperatures within the zones of the substrate block comprises electrically coupling the at least one heater strip to a heater controller.

19. The method of claim 18, wherein the at least one heater strip comprises a plurality of resistive elements electrically coupled to the heater controller, wherein the plurality of resistive elements comprise individual resistive elements distributed along the at least one heater strip.

20. The method of claim 19, wherein adjacent ones of the plurality of resistive elements comprise different resistances.

21. The method of claim 19, wherein adjacent ones of the plurality of resistive elements have progressively smaller resistances wherein temperature decreases along the at least one heater strip from a first resistive element having a highest resistance to a terminal resistive element having a lowest resistance.

22. The method of claim 19, wherein adjacent ones of the plurality of resistive elements have progressively larger resistances, wherein temperature decreases along the at least one heater strip from a first resistive element having a lowest resistance to a terminal resistive element having a highest resistance.
